(19) United States
(12) Patent Application Publication
(10) Pub. No.: US 2014/0103378 A1
(43) Pub. Date: Apr. 17, 2014

(54) LIGHT-EMITTING DIODE STRUCTURE

(71) Applicant: Lextar Electronics Corporation, Hsinchu (TW)

(72) Inventor: Su-Hon Lin, Keelung City (TW)

(73) Assignee: Lextar Electronics Corporation, Hsinchu (TW)

(21) Appl. No.: 13/952,709

(22) Filed: Jul. 29, 2013

(30) Foreign Application Priority Data
Oct. 16, 2012 (TW) 101138116

(51) Int. Cl. H01L 33/58

(52) U.S. Cl. CPC H01L 33/58
USPC 257/98

(57) ABSTRACT

A light-emitting diode structure is provided. The light-emitting diode structure comprises a substrate, a light-emitting diode device, a ring-shaped dam and an optical lens. The substrate has an upper surface. The light-emitting diode device is disposed on the upper surface of the substrate for emitting a first light having a first wavelength. The ring-shaped dam is disposed on the upper surface of the substrate, and surrounds the light-emitting diode device. The optical lens is disposed on the substrate, and encapsulates the ring-shaped dam and the light-emitting diode device. The optical lens and the ring-shaped dam and the light-emitting diode device form a cavity.

This application claims the benefit of Taiwan application Serial No. 101138116, filed Oct. 16, 2012, the subject matter of which is incorporated herein by reference.

### BACKGROUND OF THE INVENTION

1. Field of the Invention

The invention relates in general to a light-emitting diode structure, and more particularly to a light-emitting diode structure capable of improving extraction efficiency.

2. Description of the Related Art

The conventional light-emitting diode structure comprises a substrate and a light emitting diode disposed on the substrate. A light can be emitted from both an active surface and a lateral surface of the light emitting diode. However, the light emitted from the lateral surface of the light emitting diode will be wasted and cannot be utilized, hence deteriorating the extraction efficiency of the light-emitting diode structure.

### SUMMARY OF THE INVENTION

The invention is directed to a light-emitting diode structure capable of improving the problem of the extraction efficiency of the light-emitting diode structure being too low.

According to an embodiment of the present invention, a light-emitting diode structure is provided. The light-emitting diode structure comprises a substrate, a light-emitting diode device, a ring-shaped dam and an optical lens. The substrate has an upper surface. The light-emitting diode device is disposed on the upper surface of the substrate for emitting a first light having a first wavelength. The ring-shaped dam is disposed on the upper surface of the substrate, and surrounds the light-emitting diode device. The optical lens is disposed on the substrate, and encapsulates a ring-shaped dam and a light-emitting diode device surrounded by the ring-shaped dam. A cavity is formed between the optical lens and the ring-shaped dam and the light-emitting diode device.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1A shows a cross-sectional view of a light-emitting diode structure according to of the invention an embodiment;

FIG. 1B shows a top view of FIG. 1A;

FIG. 2 shows a cross-sectional view of a light-emitting diode structure according to another embodiment of the invention; and

FIG. 3 shows a cross-sectional view of a light-emitting diode structure according to another embodiment of the invention.

### DETAILED DESCRIPTION OF THE INVENTION

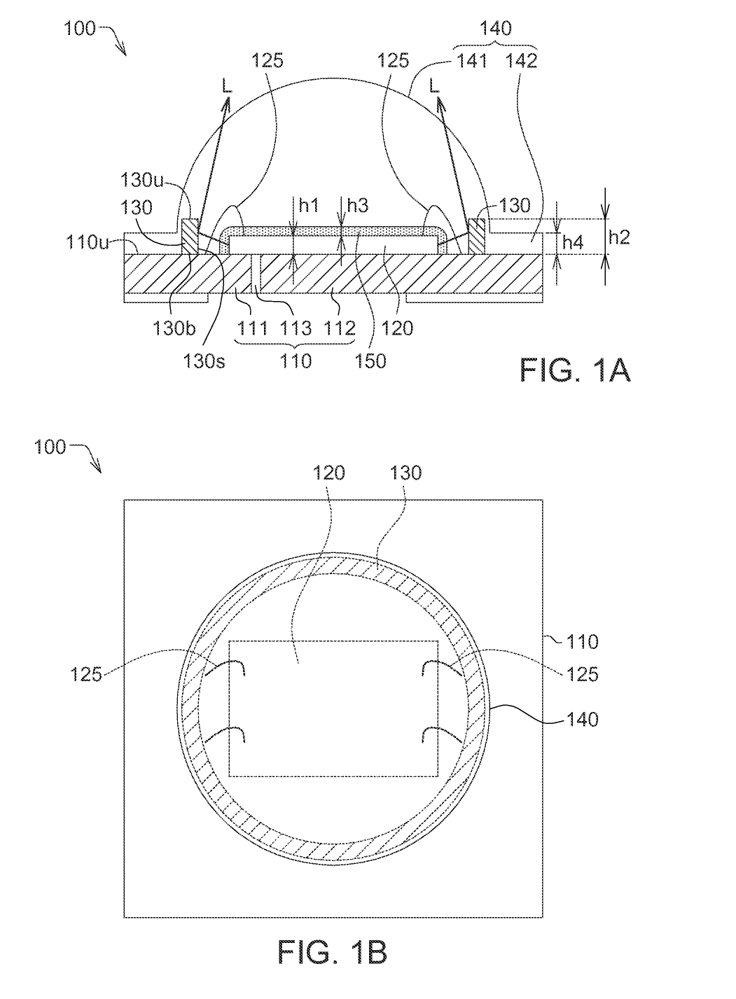

Referring to FIGS. 1A and 1B. FIG. 1A shows a cross-sectional view of a light-emitting diode structure according to of the invention an embodiment. FIG. 1B shows a top view of FIG. 1A.

As indicated in FIG. 1A, the light-emitting diode structure 100 comprises a substrate 110, a light-emitting diode device 120, a ring-shaped dam 130, an optical lens 140, and a wavelength conversion material layer 150.

The substrate 110 comprises a first electrode 111, a second electrode 112, and an insulation layer 113, wherein the insulation layer 113 electrically isolates the first electrode 111 from the second electrode 112. In the present example, the substrate 110 is such as a metal substrate, and can also be a ceramic substrate or a composite material substrate. In addition, the substrate 110 has an upper surface 110u.

The light-emitting diode device 120 is a visible light emitting diode chip emitting a visible light or an ultraviolet light emitting diode chip, wherein the visible light is such as blue light, green light or red light. The light-emitting diode device 120 is disposed on the upper surface 110u of the substrate 110 for emitting a first light L having a first wavelength. Moreover, at least two solder wires 125 connect the light-emitting diode device 120 and the substrate 110 for electrically connecting the light-emitting diode device 120 with the substrate 110. In another example, the light-emitting diode device 120 can be a flip chip; under such circumstance, the solder wires 125 can be omitted.

The ring-shaped dam 130 is disposed on the upper surface 110u of the substrate 110, and surrounds the light-emitting diode device 120. The ring-shaped dam 130 can be formed by the insulating material or the conductive material, wherein the insulating material is such as silicone, and the conductive material is such as a metal. The ring-shaped dam 130 and the substrate 110 are electrically isolated from each other. For example, if the substrate 110 is a metal substrate, then the ring-shaped dam 130 can be formed by an insulating material such as silicone. If the substrate is a ceramic substrate, then the ring-shaped dam 130 can be formed by a conductive material or an insulating material.

The ring-shaped dam 130 can be formed by a transparent or a light blocking material. If the ring-shaped dam 130 is formed by a light permeable material, the refraction index of the ring-shaped dam 130 is different from that of the optical lens 140, such that the light entering the ring-shaped dam 130 still can be refracted towards the protruding portion 141 (disclosed hereinafter) of the optical lens 140 and emitted off the light-emitting diode structure 100. If the ring-shaped dam 130 is formed by a light blocking material, then the ring-shaped dam 130 is formed by a material having high reflectivity. For example, the ring-shaped dam 130 is formed by a metal, or a reflective layer is pasted on the surface of the ring-shaped dam 130. Besides, the ring-shaped dam 130 can be formed by way of spreading process, metal decomposition process, mold casting or photolithography.

The inner lateral surface 130s of the ring-shaped dam 130 is a plane perpendicular to the upper surface 110u of the substrate 110. In another example, the inner lateral surface 130s of the ring-shaped dam 130 is an oblique plane inclined towards the upper surface 110u of the substrate 110. In the present example, the thickness of the ring-shaped dam 130 is uniform. However, the thickness of the ring-shaped dam 130 is getting shrinking or expanding in a direction from the upper surface 130u towards the lower surface 130b of the ring-shaped dam 130. Moreover, the inner lateral surface 130s of the ring-shaped dam 130 can be a smooth surface or form a scattering structure such as a structured pattern or a rough surface, wherein the structured pattern is such as a photonic crystal pattern. The scattering structure can scatter the light entering the inner lateral surface 130s of the ring-shaped dam 130 for increasing the extraction efficiency of the light-emitting diode structure 100. Through the design of the shape and/or surface roughness of the inner lateral surface 130s of the ring-shaped dam 130, the path of reflecting, refracting or scattering the light emitted from the inner lateral surface 130s can be adjusted.

In the present embodiment, the shape of the ring-shaped dam 130 is a closed ring (FIG. 1B). In another example, the shape of the ring-shaped dam 130 can be an open ring. In the present example, the shape of the ring-shaped dam 130 is a circle (FIG. 1B). In another example, the shape of the ring-shaped dam 130 can be an ellipse, a polygon or any form, wherein polygon is such as a triangle or a rectangle.

The ring-shaped dam 130 has a second thickness h2, the wavelength conversion material layer 150 has a third thickness h3, and the light-emitting diode device 120 has a first thickness h1, wherein the second thickness h2 at least is larger than the sum of the first thickness h1 and the third thickness h3, such that the light emitted from a lateral surface of the light-emitting diode device 120 is almost emitted to the ring-shaped dam 130. In an example, the first thickness h1 of the light-emitting diode device 120 is about 150 μm, and the second thickness h2 of the ring-shaped dam 130 is between 170˜250 μm.

In comparison to the conventional light-emitting diode structure, the luminance and white light conversion efficiency of the light-emitting diode structure 100 of the embodiment of the invention are increased by 7˜12% due to the design of the ring-shaped dam 130. Furthermore, when the ring-shaped dam 130 has a scattering structure, the luminance and white light conversion efficiency can be increased by 12˜17%. The light emitting angle of the light-emitting diode structure 100 of the embodiment of the invention can be controlled to be 120 degrees being a suitable angle for illumination purpose. In another example, the light emitting angle of the light-emitting diode structure 100 can be other than 120 degrees.

The optical lens 140 is disposed on the substrate 110, and encapsulates the ring-shaped dam 130 and the light-emitting diode device 120 surrounded by the ring-shaped dam 130. A cavity is formed between the optical lens 140 and the ring-shaped dam 130 and the light-emitting diode device 120. The optical lens 140 can be formed by a sealing material. For example, the cavity of the optical lens 140 can be filled up with a sealing material.

The optical lens 140 comprises a protruding portion 141 and an extending portion 142. The protruding portion 141 is formed on the upper surface 110u of the substrate 110, and encapsulates the light-emitting diode device 120 and the ring-shaped dam 130.

The extending portion 142 of the optical lens 140 is formed in an edge region of the substrate 110 and extended outwardly from the bottom of the protruding portion 141 in a direction away from the ring-shaped dam 130. Due to the design of the extending portion 142, during the process of mold compressing the optical lens 140, the upper mold and the lower mold tightly compress the material of the optical lens 140, such that after the mold compression process, the optical lens 140 can be tightly fixed on the substrate 110. Due to the design of the ring-shaped dam 130, the light emitted from the lateral surface of the light-emitting diode device 120 is avoided entering the extending portion 142 and is guided by the ring-shaped dam 130 to be emitted off the light-emitting diode structure 100 from the protruding portion 141. Furthermore, if the ring-shaped dam 130 is omitted, a part of the light will enter the extending portion 142 and become wasted due to total reflection, and accordingly the extraction efficiency is deteriorated. In another example, the thickness h4 of the extending portion 142 is smaller than the second thickness h2 of the ring-shaped dam 130, such that almost whole of the light emitted to the extending portion 142 enters the ring-shaped dam 130.

In addition, the optical lens 140 can be formed by way of glue dispensing, adhesive potting, adhesive injecting, injection molding or mold casting.

The wavelength conversion material layer 150 encapsulate an active surface of the light-emitting diode device 120 for converting the first light having a first wavelength into a second light L having a second wavelength, wherein the second wavelength is larger than the first wavelength. The wavelength conversion material layer 150 is selected from phosphor, pigments, paints or a combination thereof.

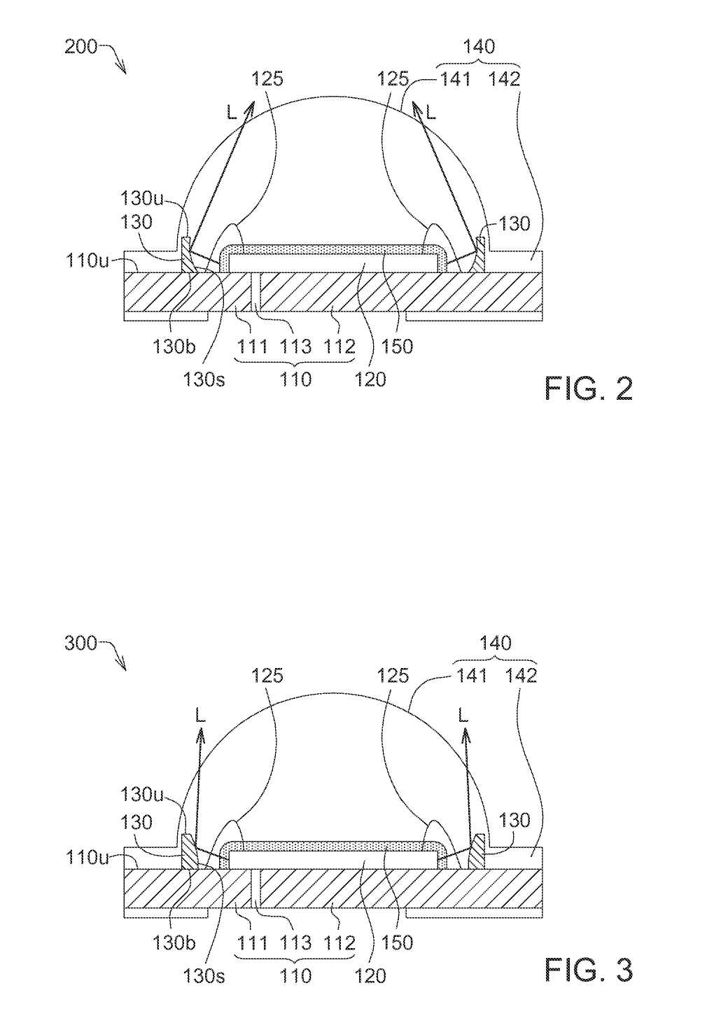

Referring to FIG. 2, a cross-sectional view of a light-emitting diode structure according to another embodiment of the invention is shown. The light-emitting diode structure 200 comprises a substrate 110, a light-emitting diode device 120, a ring-shaped dam 130, an optical lens 140 and a wavelength conversion material layer 150. In the present example, the inner lateral surface 130s of the ring-shaped dam 130 is a concave surface, and the thickness of the ring-shaped dam 130 is getting expanding in a direction from the upper surface 130u of the ring-shaped dam 130 towards the lower surface 130b. In another example, the inner lateral surface 130s of the ring-shaped dam 130 is also a concave surface, but the thickness of the ring-shaped dam 130 is getting shrinking in a direction from the upper surface 130u of the ring-shaped dam 130 towards the lower surface 130b.

Referring to FIG. 3, a cross-sectional view of a light-emitting diode structure according to another embodiment of the invention is shown. The light-emitting diode structure 300 comprises a substrate 110, a light-emitting diode device 120, a ring-shaped dam 130, an optical lens 140 and a wavelength conversion material layer 150. In the present example, the inner lateral surface 130s of the ring-shaped dam 130 is a convex surface, and the thickness of the ring-shaped dam 130 is getting expanding in a direction from the upper surface 130u of the ring-shaped dam 130 towards the lower surface 130b. In another example, the inner lateral surface 130s of the ring-shaped dam 130 is also a convex surface, but the thickness of the ring-shaped dam 130 is getting shrinking in a direction from the upper surface 130u of the ring-shaped dam 130 towards the lower surface 130b.

As disclosed above, the inner lateral surface 130s of the ring-shaped dam 130 can be a plane, a curved plane or a combination thereof. The thickness of the ring-shaped dam 130 can remain the same, be getting shrinking or getting expanding in a direction from the upper surface 130u towards the lower surface 130b, or the change in the thickness of the ring-shaped dam 130 is a combination thereof.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting diode structure, comprising:
a substrate having an upper surface;
a light-emitting diode device disposed on the upper surface of the substrate for emitting a first light having a first wavelength;
a ring-shaped dam disposed on the upper surface of the substrate and surrounding the light-emitting diode device; and
an optical lens disposed on the substrate and encapsulating the ring-shaped dam and the light-emitting diode device surrounded by the ring-shaped dam, wherein a cavity is formed between the optical lens and the ring-shaped dam and the light-emitting diode device.

2. The light-emitting diode structure according to claim 1, further comprising:
a wavelength conversion material layer covering a surface of the light-emitting diode device and converting the first light having the first wavelength into a second light having a second wavelength, wherein the second wavelength is larger than the first wavelength;
wherein, the wavelength conversion material layer has a third thickness, the light-emitting diode device has a first thickness, the ring-shaped dam has a second thickness, and the second thickness at least is larger than the sum of the first thickness and the third thickness.

3. The light-emitting diode structure according to claim 2, wherein the wavelength conversion material layer is formed by a material selected from a group consisting of phosphor, pigments, paints or a combination thereof.

4. The light-emitting diode structure according to claim 3, wherein the ring-shaped dam and the substrate are electrically isolated from each other.

5. The light-emitting diode structure according to claim 4, wherein the refraction index of the optical lens and the refraction index of the ring-shaped dam are different from each other.

6. The light-emitting diode structure according to claim 5, wherein the optical lens can be formed by a sealing material.

7. The light-emitting diode structure according to claim 6, wherein the cavity of the optical lens is filled up with a sealing material.

8. The light-emitting diode structure according to claim 5, wherein the ring-shaped dam is formed by silicone or a metal.

9. The light-emitting diode structure according to claim 1, wherein the light-emitting diode device is formed by a visible light emitting diode chip emitting a visible light or an ultraviolet light emitting diode chip, and the visible light is blue light, green light, or red light.

10. The light-emitting diode structure according to claim 2, wherein the light-emitting diode device is formed by a visible light emitting diode chip emitting a visible light or an ultraviolet light emitting diode chip, and the visible light is blue light, green light, or red light.

11. The light-emitting diode structure according to claim 3, wherein the light-emitting diode device is formed by a visible light emitting diode chip emitting a visible light or an ultraviolet light emitting diode chip, and the visible light is blue light, green light, or red light.

12. The light-emitting diode structure according to claim 4, wherein the light-emitting diode device is formed by a visible light emitting diode chip emitting a visible light or an ultraviolet light emitting diode chip, and the visible light is blue light, green light, or red light.

13. The light-emitting diode structure according to claim 5, wherein the light-emitting diode device is formed by a visible light emitting diode chip emitting a visible light or an ultraviolet light emitting diode chip, and the visible light is blue light, green light, or red light.

14. The light-emitting diode structure according to claim 6, wherein the light-emitting diode device is formed by a visible light emitting diode chip emitting a visible light or an ultraviolet light emitting diode chip, and the visible light is blue light, green light, or red light.

15. The light-emitting diode structure according to claim 7, wherein the light-emitting diode device is formed by a visible light emitting diode chip emitting a visible light or an ultraviolet light emitting diode chip, and the visible light is blue light, green light, or red light.

16. The light-emitting diode structure according to claim 8, wherein the light-emitting diode device is formed by a visible light emitting diode chip emitting a visible light or an ultraviolet light emitting diode chip, and the visible light is blue light, green light, or red light.

17. The light-emitting diode structure according to claim 1, wherein the optical lens is formed by way of glue dispensing, adhesive potting, adhesive injecting, injection molding or mold casting.

18. The light-emitting diode structure according to claim 1, wherein an extending portion is formed at a bottom edge by which the optical lens contacts the substrate and is extended outwardly in a direction away from the ring-shaped dam.
